(19) United States
(12) Patent Application Publication
(10) Pub. No.: US 2020/0381045 A1
(43) Pub. Date: Dec. 3, 2020

(54) SEMICONDUCTOR DEVICE AND ERROR DETECTION METHOD

(71) Applicant: NEC Corporation, Minato-ku, Tokyo (JP)

(72) Inventors: Toshitsugu SAKAMOTO, Tokyo (JP); Ryusuke NEBASHI, Tokyo (JP); Makoto MIYAMURA, Tokyo (JP); Xu BAI, Tokyo (JP); Yukihide TSUJI, Tokyo (JP)

(73) Assignee: NEC Corporation, Minato-ku, Tokyo (JP)

(21) Appl. No.: 16/970,495

(22) PCT Filed: Mar. 12, 2019
(86) PCT No.: PCT/JP2019/009845

§ 371 Date: Aug. 17, 2020

(30) Foreign Application Priority Data
Mar. 14, 2018 (JP) 2018-046136

(51) Int. Cl. G11C 13/00; H03K 19/177; H01L 27/24; H01L 45/00

(52) U.S. Cl. CPC G11C 13/004; G11C 13/0069; G11C 13/0026; G11C 2213/75; H01L 27/2454; H01L 45/1253; H03K 19/177

(57) ABSTRACT

A semiconductor device which includes: a switch array in which a switch cell including a variable resistance switch is arranged at each location where a plurality of wires constituting a crossbar switch intersect; a first selection circuit that selects all of the variable resistance switches included in the switch array; a second selection circuit that selects any of the variable resistance switches included in the switch array; a reading circuit that reads a state of the variable resistance switch selected by any of the first selection circuit and the second selection circuit; and an error detection circuit that detects, based on a state of the variable resistance switch read by the reading circuit, an error in at least any of the variable resistance switches included in the switch array.

### TECHNICAL FIELD

The present invention relates to a semiconductor device on which a logic circuit is formed and an error detection method. In particular, the present invention relates to a logic integrated circuit and a semiconductor device that include a non-volatile variable resistance element.

### BACKGROUND ART

A programmable logic integrated circuit such as a field-programmable gate array (FPGA) is an integrated circuit of which function can be programmed after manufacturing. The programmable logic integrated circuit, as compared with a custom-designed application specific integrated circuit (ASIC), tends to have a large chip size due to a large number of transistors. In the FPGA, signal switching is performed by a crossbar switch, and information on a switching destination is held in a memory. In a general programmable logic integrated circuit, signal switching is performed by a pass transistor, and information on a switching destination is held in a memory such as a static random access memory (SRAM). The pass transistor and the SRAM that achieve programmability of the programmable logic integrated circuit occupy a large area in the entire circuit. Use of the pass transistor and the SRAM is an example of a factor that increases a chip size of the programmable logic integrated circuit as compared with the ASIC.

NPL 1 discloses a programmable logic integrated circuit using a variable resistance switch. The variable resistance switch in NPL 1 enables to simultaneously achieve a function of the pass transistor turning on/off a signal and a function of the SRAM holding configuration information. The variable resistance switch in NPL 1 can be formed on a wiring layer of the integrated circuit, and thus, enables to reduce a chip size as compared with the case of using the pass transistor and the SRAM.

PTL 1 discloses a variable resistance switch utilizing movement and electrochemical reaction of a metal ion in a variable resistance layer. The variable resistance switch in PTL 1 has a three-layer structure in which an active electrode, a variable resistance layer, and an inactive electrode are stacked in order. The active electrode supplies a metal ion to the variable resistance layer depending on a voltage to be applied. Meanwhile, the inactive electrode does not supply any metal ion to the variable resistance layer. PTL 1 uses copper as one example of the active electrode. The copper is used as a material for multilayer interconnections of the integrated circuit. Thus, when one of the multilayer interconnections including copper serves as the active electrode, a structure of the integrated circuit is simplified, and manufacture processes can be reduced.

PTL 1 also discloses a three-terminal variable resistance switch in which two variable resistance switches are connected in series. The variable resistance switch in PTL 1 enables to improve reliability of an off state, and enables to lower a programming voltage.

In the variable resistance switch, a low-resistance state is defined as an on state, and a high-resistance state is defined as an off state. In the three-terminal variable resistance switch, two variable resistance switches being in the low-resistance state are defined as in the on state, and the two variable resistance switches being in the high-resistance state are defined as in the off state. A voltage necessary for shifting the variable resistance switch from the high-resistance state to the low-resistance state is called a programming voltage. The programming voltage is desirably equal to or less than 2 V. When the variable resistance switch is applied to the programmable logic integrated circuit, it is necessary that application of a working voltage (for example, 1 V) of the integrated circuit does not cause any resistance change.

For example, reliability of the off state is necessary to such a degree that the variable resistance switch being in the high-resistance state does not shift to the low-resistance state, even when 1 V equivalent to the working voltage is continuously applied to the variable resistance switch for ten years being supposed as a lifetime of the integrated circuit. In the variable resistance switch, this problem is solved, and high reliability of the off state is acquired with the reduced programming voltage.

When the variable resistance switch is applicable to the programmable logic integrated circuit, a chip area can be significantly reduced as compared with the case of using the SRAM and the pass transistor. NPL 1 discloses the programmable logic integrated circuit using a crossbar switch including the variable resistance switch. The programmable logic integrated circuit in NPL 1 has excellent low power consumption performance and low signal delay performance as compared with the FPGA using the SRAM and the pass transistor.

In order to achieve a function (an application circuit) desired by a user in the programmable logic integrated circuit, a large number of switches or memories are programmed. When an application circuit is programmed in the programmable logic integrated circuit, verification as to whether the application circuit is correctly programmed is carried out.

### CITATION LIST

### Patent Literature

[PTL 1] International Publication WO 2012/043502

### Non Patent Literature

[NPL 1] M. Miyamura et al., “0.5-V Highly Power-Efficient Programmable Logic using Nonvolatile Configuration Switch in BEOL”, Proceedings of the 2015 ACM/SIGDA International Symposium on Field-Programmable Gate Arrays, pp.236 to 239, 2015

### SUMMARY OF INVENTION

### Technical Problem

The programmable logic integrated circuits in PTL 1 and NPL 1 have a possibility that correct computation may not be performed due to a wrong connection, or collision of signals may cause a failure in the integrated circuit, in the following two cases. The first case is a case in which the variable resistance switch that has to be programmed into the low-resistance state (on state) is in the high-resistance state (off state). The second case is a case in which the variable resistance switch that has to be in the high-resistance state (off state) is in the low-resistance state (on state).

The following two factors are examples of a cause of incorrectly setting on/off states of the variable resistance switch. The first factor is that a transition of the resistance state is incorrectly made when the variable resistance switch is programmed. The second factor is that an unintended transition of the resistance state occurs due to external factors such as power supply noise, environmental temperature, and a high-energy cosmic ray.

In order to confirm normality of on/off states of the variable resistance switch, it is necessary to read on/off states of each variable resistance switch. Since it takes time to read on/off states of all the variable resistance switches constituting the programmable logic integrated circuit, reduction of the time is a problem.

An object of the present invention is to provide a semiconductor device that solves the above-described problem and is capable of quickly determining an error in a variable resistance switch constituting a crossbar switch.

### Solution to Problem

A semiconductor device according to one aspect of the present invention includes: a switch array in which a switch cell including a variable resistance switch is arranged at each location where a plurality of wires constituting a crossbar switch intersect; a first selection circuit that selects all of the variable resistance switches included in the switch array; a second selection circuit that selects any of the variable resistance switches included in the switch array; a reading circuit that reads a state of the variable resistance switch selected by any of the first selection circuit and the second selection circuit; and an error detection circuit that detects, based on the state of the variable resistance switch read by the reading circuit, an error in at least any of the variable resistance switches included in the switch array.

An error detection method according to one aspect of the present invention includes: in a switch array in which a switch cell including a variable resistance switch is arranged at each location where a plurality of wires constituting a crossbar switch intersect, selecting all of the variable resistance switches or any of the variable resistance switches included in the switch array; reading a state of the selected variable resistance switch; and detecting, based on the read state of the variable resistance switch, an error in at least any of the variable resistance switches included in the switch array.

### ADVANTAGEOUS EFFECTS OF INVENTION

The present invention is able to provide a semiconductor device capable of quickly determining an error in a variable resistance switch constituting a crossbar switch.

### BRIEF DESCRIPTION OF DRAWINGS

FIG. 1 is a block diagram illustrating one example of a configuration of a programmable logic integrated circuit according to a first example embodiment of the present invention.

FIG. 2 is a diagram illustrating one example of a resistance state of a variable resistance switch included in the programmable logic integrated circuit according to the first example embodiment of the present invention.

FIG. 3 is a diagram illustrating one example of another resistance state of the variable resistance switch included in the programmable logic integrated circuit according to the first example embodiment of the present invention.

FIG. 4 is a block diagram illustrating one example of a configuration of a programmable logic integrated circuit according to a second example embodiment of the present invention.

FIG. 5 is a schematic diagram illustrating one example of a circuit configuration of a programmable logic core in a programmable logic integrated circuit according to a third example embodiment of the present invention.

FIG. 6 is a circuit diagram illustrating a configuration of an all column selection circuit included in the programmable logic integrated circuit according to the third example embodiment of the present invention.

FIG. 7 is a circuit diagram illustrating a configuration of an all row selection circuit included in the programmable logic integrated circuit according to the third example embodiment of the present invention.

FIG. 8 is a flowchart for describing a method (setting) of writing a first variable resistance element of a switch cell included in the programmable logic integrated circuit according to the third example embodiment of the present invention.

FIG. 9 is a flowchart for describing a method (setting) of writing a second variable resistance element of the switch cell included in the programmable logic integrated circuit according to the third example embodiment of the present invention.

FIG. 10 is a flowchart for describing a method (resetting) of writing the first variable resistance element of the switch cell included in the programmable logic integrated circuit according to the third example embodiment of the present invention.

FIG. 11 is a flowchart for describing a method (resetting) of writing the second variable resistance element of the switch cell included in the programmable logic integrated circuit according to the third example embodiment of the present invention.

FIG. 12 is a flowchart for describing a first method of reading the first variable resistance element of the switch cell included in the programmable logic integrated circuit according to the third example embodiment of the present invention.

FIG. 13 is a flowchart for describing a first method of reading the second variable resistance element of the switch cell included in the programmable logic integrated circuit according to the third example embodiment of the present invention.

FIG. 14 is a flowchart for describing a second method of reading the first variable resistance element of the switch cell included in the programmable logic integrated circuit according to the third example embodiment of the present invention.

FIG. 15 is a flowchart for describing a second method of reading the second variable resistance element of the switch cell included in the programmable logic integrated circuit according to the third example embodiment of the present invention.

FIG. 16 is a flowchart for describing a third method of reading the switch cell included in the programmable logic integrated circuit according to the third example embodiment of the present invention.

### Example Embodiment

Example embodiments of the present invention will be described below by using the drawings. However, the example embodiments described below include technically preferable limitations to carry out the present invention, but the scope of the invention is not limited to the following. Throughout all the drawings used for description of the following example embodiments, similar parts are assigned with identical reference signs unless there is a special reason. In the following example embodiments, repeated description relating to similar configurations and operations may be omitted. A direction of an arrow in each drawing indicates one example, and is not intended to limit a direction of a signal between blocks.

### First Example Embodiment

First, a programmable logic integrated circuit (also referred to as a semiconductor device) according to a first example embodiment of the present invention will be described with reference to the drawings.

### Configuration

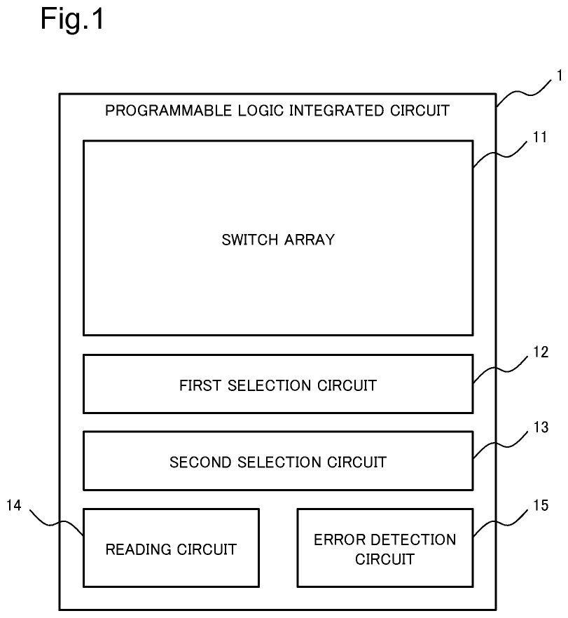

FIG. 1 is a block diagram illustrating one example of a configuration of a programmable logic integrated circuit 1 according to the present example embodiment. The programmable logic integrated circuit 1 includes a switch array 11, a first selection circuit 12, a second selection circuit 13, a reading circuit 14, and an error detection circuit 15.

The switch array 11 includes a plurality of three-terminal variable resistance switches. The variable resistance switch is included in a switch cell arranged at each location where a plurality of wires constituting a crossbar switch intersect. The variable resistance switch constituting the switch array 11 has a configuration in which two variable resistance elements are connected in series. According to the present example embodiment, the variable resistance switch has a configuration in which a first variable resistance element and a second variable resistance element are connected in series. Each of the first variable resistance element and the second variable resistance element has a configuration in which an active electrode, a variable resistance layer, and an inactive electrode are stacked. Hereinafter, it is assumed that the first variable resistance element and the second variable resistance element included in the variable resistance switch have a similar configuration.

The first selection circuit 12 simultaneously selects a plurality of variable resistance elements.

When the first selection circuit 12 simultaneously selects a plurality of first variable resistance elements, inactive electrodes of the plurality of first variable resistance elements are connected to each other, and active electrodes of the plurality of first variable resistance elements are connected to each other. A node where the inactive electrodes of the plurality of first variable resistance elements are connected to each other and a node where the active electrodes of the plurality of first variable resistance elements are connected to each other are each connected to the reading circuit 14.

Similarly, when the first selection circuit 12 simultaneously selects a plurality of second variable resistance elements, inactive electrodes of the plurality of second variable resistance elements are connected to each other, and active electrodes of the plurality of second variable resistance elements are connected to each other. A node where the inactive electrodes of the plurality of second variable resistance elements are connected to each other and a node where the active electrodes of the plurality of second variable resistance elements are connected to each other are each connected to the reading circuit 14.

When at least one of the plurality of variable resistance switches is in an on state, a resistance state between both of the active electrode and the inactive electrode is read as an on state by the reading circuit 14. On the other hand, when all of the plurality of variable resistance switches are in an off state, a resistance state between both of the active electrode and the inactive electrode is read as an off state by the reading circuit 14.

The second selection circuit 13 selects at least one variable resistance element among the plurality of variable resistance switches.

The second selection circuit 13 individually senses a resistance state of all the variable resistance switches included in the programmable logic integrated circuit 1. The second selection circuit 13 is able to select at least one first variable resistance element. Similarly, the second selection circuit 13 is able to select at least one second variable resistance element.

The reading circuit 14 senses a resistance state of the variable resistance element constituting the variable resistance switch.

When at least one of the plurality of variable resistance elements is in an on state, the reading circuit 14 reads a resistance state between both of the active electrode and the inactive electrode as an on state. On the other hand, when all of the plurality of variable resistance elements are in an off state, the reading circuit 14 reads the resistance state between both of the active electrode and the inactive electrode as an off state.

The reading circuit 14 outputs, to the error detection circuit 15, output data depending on a resistance state of the variable resistance element constituting the variable resistance switch. For example, the reading circuit 14 outputs, as output data IQ, data 1 when a resistance value of the variable resistance element is smaller than a predetermined value, or data 0 when the resistance value of the variable resistance element is larger than the predetermined value.

The error detection circuit 15 determines, based on the output data IQ from the reading circuit 14, whether an error is present in a resistance state of the switch cell. For example, in the case of the output data 0, the error detection circuit 15 determines that the resistance state of the selected variable resistance element is an expected state (off state). For example, in the case of the output data 1, the error detection circuit 15 determines that the resistance state of the selected variable resistance element is not an expected state (a switch in an on state is included). In other words, the error detection circuit 15 determines that an error is present when at least one resistance state among the selected variable resistance elements is not an expected state (a switch in an on state is included).

Variable Resistance Switch

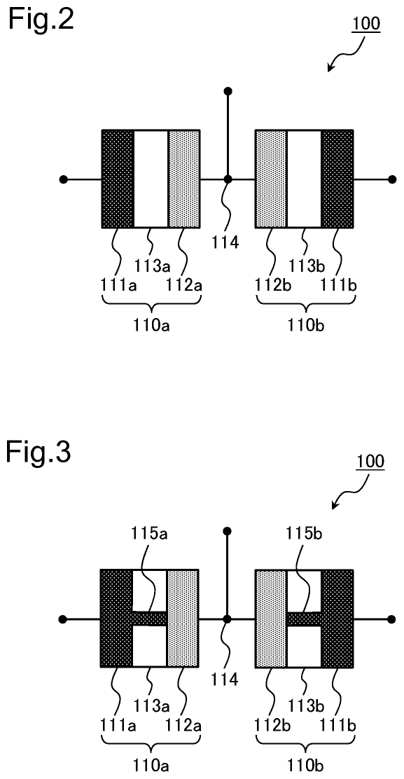

Herein, a variable resistance switch included in the switch array 11 provided in the programmable logic integrated circuit 1 will be described with reference to the drawings. FIGS. 2 and 3 are conceptual diagrams illustrating one example of a variable resistance switch 100 constituting the switch array 11.

The variable resistance switch 100 has a configuration in which a first variable resistance element 110a and a second variable resistance element 110b are connected in series. Hereinafter, when the first variable resistance element 110a and the second variable resistance element 110b are not distinguished from each other, the first variable resistance element 110a and the second variable resistance element 110b will be described as a variable resistance element 110.

The first variable resistance element 110a includes an active electrode 111a, an inactive electrode 112a, and a variable resistance layer 113a. Similarly, the second variable resistance element 110b includes an active electrode 111b, an inactive electrode 112b, and a variable resistance layer 113b. The inactive electrode 112a of the first variable resistance element 110a and the inactive electrode 112b of the second variable resistance element 110b are connected to each other and form a common node 114. Hereinafter, when the active electrode 111a and the active electrode 111b, the inactive electrode 112a and the inactive electrode 112b, and the variable resistance layer 113a and the variable resistance layer 113b are not distinguished from each other, the active electrode 111a and the active electrode 111b, the inactive electrode 112a and the inactive electrode 112b, and the variable resistance layer 113a and the variable resistance layer 113b will be described as an active electrode 111, an inactive electrode 112, and a variable resistance layer 113, respectively.

The variable resistance element 110 has two resistance states: a high-resistance state (FIG. 2) and a low-resistance state (FIG. 3). According to the present example embodiment, the high-resistance state is defined as an off state (FIG. 2), and the low-resistance state is defined as an on state (FIG. 3). When the variable resistance element 110 is in the on state, a signal given by a voltage level passes through the variable resistance element 110. On the other hand, when the variable resistance element 110 is in the off state, a signal given by a voltage level is blocked by the variable resistance element 110.

The resistance states of the variable resistance element 110 are associated with 1 (data 1) and 0 (data 0) of configuration information. According to the present example embodiment, the low-resistance state (on state) is defined as data 1, and the high-resistance state (off state) is defined as data 0.

Herein, an operation of making transition of the resistance state of the first variable resistance element 110a and the second variable resistance element 110b (the variable resistance element 110) constituting the variable resistance switch 100 will be described.

First, a method of causing the variable resistance element 110 to transition from the high-resistance state (off state) to the low-resistance state (on state) will be described.

In the variable resistance element 110 in the high-resistance state (off state), when a positive voltage is applied to the active electrode 111 and the inactive electrode 112 is grounded, metal such as copper included in the active electrode 111 is ionized and dissolved in the variable resistance layer 113 as a metal ion. The dissolved metal ion is reduced and deposited as metal in the variable resistance layer 113. The deposited metal forms a metal crosslink 115 connecting between the active electrode 111 and the inactive electrode 112. When the active electrode 111 and the inactive electrode 112 are electrically connected by the metal crosslink 115, the variable resistance element 110 transitions from the high-resistance state (off state) to the low-resistance state (on state).

Next, a method of causing the variable resistance element 110 to transition from the low-resistance state (on state) to the high-resistance state (off state) will be described.

In the variable resistance element 110 in the low-resistance state (on state), when the active electrode 111 is grounded and a positive voltage is applied to the inactive electrode 112, the metal crosslink 115 is dissolved in the variable resistance layer 113 as a metal ion and a part of the metal crosslink 115 is broken. When a part of the metal crosslink 115 is broken, electrical connection between the active electrode 111 and the inactive electrode 112 is lost, and the variable resistance element 110 transitions to the high-resistance state (off state). Between the active electrode 111 and the inactive electrode 112, an electrical characteristic changes due to an increase in an electrical resistance and a change in a capacitance between the electrodes, from a stage before complete breakage of the electrical connection, and, finally, the electrical connection is broken. In order to change the variable resistance element 110 from the high-resistance state (off state) to the low-resistance state (on state), a negative voltage may be applied again to the inactive electrode 112.

As described above, the on state and the off state of the switch can be achieved by using the low-resistance state and the high-resistance state of the variable resistance element 110.

When the variable resistance element 110 is caused to transition from the high-resistance state to the low-resistance state, a transient state such as a gradual decrease in a resistance between the electrodes and a change in a capacitance between the electrodes is generated at a stage before formation of the metal crosslink 115, and, finally, the metal crosslink 115 is formed between the electrodes. When the variable resistance element 110 is caused to transition from the low-resistance state to the high-resistance state, a transient state such as a gradual increase in a resistance between the electrodes and a change in a capacitance between the electrodes is generated at a stage before breakage of the connection made by the metal crosslink, and, finally, the connection between the electrodes is broken. For example, it is also possible to utilize an intermediate state between the low-resistance state and the high-resistance state by using the transient state.

For the variable resistance element 110, a variable resistance non-volatile memory element for use in a phase change random access memory (PRAM) or a resistive random access memory (ReRAM) may be used.

As described above, the programmable logic integrated circuit according to the present example embodiment includes a switch array, a first selection circuit, a second selection circuit, a reading circuit, and an error detection circuit. In the switch array, a switch cell including a variable resistance switch is arranged at each location where a plurality of wires constituting a crossbar switch intersect. For example, the variable resistance switch is constituted of two variable resistance elements connected in series. The first selection circuit selects all of the variable resistance switches included in the switch array. The second selection circuit selects any of the variable resistance switches included in the switch array. The reading circuit reads a state of the variable resistance switch selected by any of the first selection circuit and the second selection circuit. The error detection circuit detects, based on the state of the variable resistance switch read by the reading circuit, an error in at least any of the variable resistance switches included in the switch array.

According to the present example embodiment, error determination is performed based on a resistance state expected for a selected variable resistance element. The present example embodiment enables to significantly reduce read time, since selecting a plurality of variable resistance elements enables simultaneous error determination in the plurality of selected variable resistance elements. The present example embodiment is able to shorten time required for determining an error in the variable resistance element, since error determination is performed based on a resistance state of the variable resistance element, rather than setting, based on configuration information, a resistance state of a variable resistance switch included in the switch array. In other words, the present example embodiment is able to provide a programmable logic integrated circuit capable of quickly determining an error in a variable resistance switch constituting a crossbar switch.

For example, the reading circuit reads that the variable resistance switch is in the on state when at least one of the two variable resistance elements constituting the variable resistance switch is in the on state. The reading circuit reads that the variable resistance switch is in the off state when both of the two variable resistance elements constituting the variable resistance switch are in the off state. The reading circuit outputs, to the error detection circuit, output data depending on a resistance state of the variable resistance element constituting the variable resistance switch. The error detection circuit determines, based on the output data from the reading circuit, whether an error is present in a resistance state of the variable resistance switch.

For example, the first selection circuit selects one of the two variable resistance elements constituting all of the variable resistance switches included in the switch array when all of the plurality of variable resistance switches included in the switch array are expected as being in the off state. The reading circuit outputs, as the output data to the error detection circuit, a result of determining at least one resistance state among all of the variable resistance elements selected by the first selection circuit.

For example, the reading circuit determines that an error is present in at least any of the variable resistance elements included in the switch array when at least one resistance state among all of the variable resistance elements selected by the first selection circuit is the on state.

### Second Example Embodiment

Next, a programmable logic integrated circuit (also referred to as a semiconductor device) according to a second example embodiment of the present invention will be described with reference to the drawings. The present example embodiment is a more specific example embodiment of the programmable logic integrated circuit according to the first example embodiment.

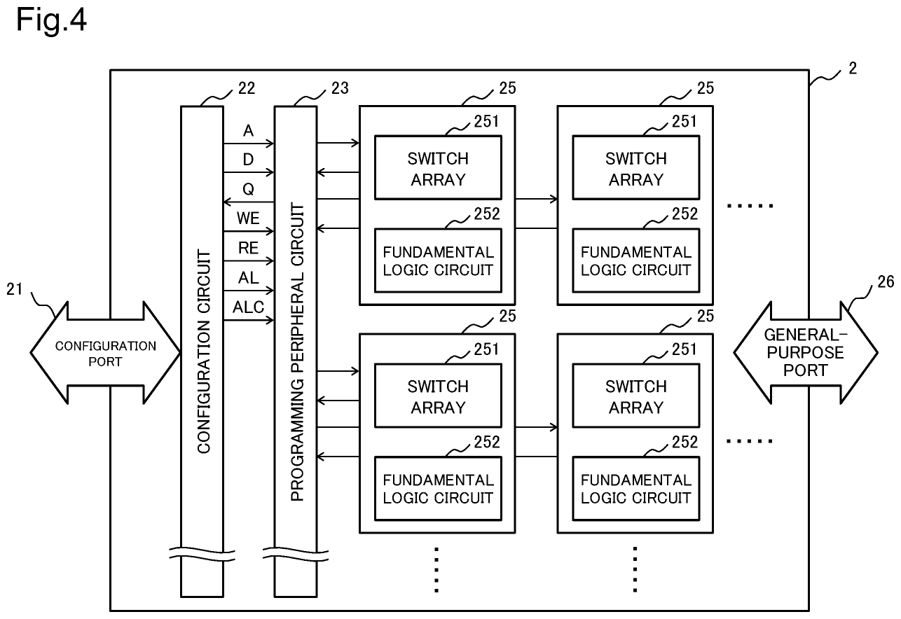

FIG. 4 is a block diagram illustrating a configuration of a programmable logic integrated circuit 2 according to the present example embodiment. The programmable logic integrated circuit 2 includes a configuration port 21, a configuration circuit 22, a programming peripheral circuit 23, a plurality of programmable logic cells 25, and a general-purpose port 26. The programmable logic cell 25 includes a switch array 251 and a fundamental logic circuit 252. An arrow in FIG. 4 indicates one example of signal flow, and is not intended to limit the signal flow.

The configuration port 21 receives an input of a signal including configuration information. The configuration port 21 outputs the input signal including the configuration information to the configuration circuit 22.

The configuration circuit 22 receives the signal including the configuration information from the configuration port 21. The configuration circuit 22 outputs a control signal to the programming peripheral circuit 23, and inputs and outputs data between the configuration circuit 22 and the programming peripheral circuit 23.

During write of a variable resistance switch, the configuration circuit 22 writes input data D in a variable resistance switch having an address A, by setting a write enable signal WE to high level.

During read of a variable resistance switch, the configuration circuit 22 receives a data output Q as data read from the variable resistance switch having the address A, by setting a read enable signal RE to high level.

The configuration circuit 22 receives the data output Q as data read from a plurality of selected variable resistance switches, by setting the read enable signal RE and an all row selection signal ALC to high level.

The configuration circuit 22 receives the data output Q as data read from all variable resistance switches included in the switch array 251, by setting the read enable signal RE and an all selection signal AL to high level.

The programming peripheral circuit 23 receives an input of the control signal from the configuration circuit 22, and inputs and outputs data between the configuration circuit 22 and the programming peripheral circuit 23. The programming peripheral circuit 23 performs, in response to the control signal from the configuration circuit 22, write and read of the switch array 251 included in the programmable logic cell 25, sensing of a resistance state, error determination in a variable resistance element, and the like.

In the programmable logic cell 25, a logic circuit based on the configuration information is configured by the programming peripheral circuit 23.

The programmable logic cell 25 acquires input data from the general-purpose port 26. The programmable logic cell 25 outputs the input data acquired from the general-purpose port 26 to the logic circuit configured based on the configuration information. The programmable logic cell 25 outputs, to the general-purpose port 26, a result of a logical operation performed by the logic circuit.

The switch array 251 includes a plurality of variable resistance switches. In the switch array 251, a connection state of wires is changed by setting, based on the configuration information of the logic circuit, a resistance state of the variable resistance switch. Consequently, logic configuration and reconfiguration of the programmable logic cell 25 is possible.

The fundamental logic circuit 252 includes a lookup table (not illustrated), a flip-flop (not illustrated), and the like. According to the present example embodiment, the fundamental logic circuit 252 is optional, and thus, detailed description will be omitted.

The general-purpose port 26 receives input data. The general-purpose port 26 outputs the received input data to the programmable logic cell 25.

The above is the description about the configuration of the programmable logic integrated circuit 2 according to the present example embodiment.

As described above, the present example embodiment is able to provide a programmable logic integrated circuit capable of quickly determining an error in a variable resistance switch constituting a crossbar switch, similarly to the first example embodiment.

For example, the programmable logic integrated circuit according to the present example embodiment includes a plurality of programmable logic cells that include a switch cell and a fundamental logic circuit constituted of a lookup table and a flip-flop. The programmable logic integrated circuit according to the present example embodiment further includes a configuration circuit that acquires configuration information of a logic circuit to be configured in the programmable logic cell and transmits a signal for configuring the logic circuit in the programmable logic cell, based on the acquired configuration information. The programmable logic integrated circuit according to the present example embodiment further includes a general-purpose port that inputs data to be processed by the logic circuit configured in the programmable logic cell and outputs a result of an operation performed by the logic circuit.

### Third Example Embodiment

Next, a programmable logic integrated circuit (also referred to as a semiconductor device) according to a third example embodiment of the present invention will be described with reference to the drawings. The present example embodiment is a more specific example embodiment of the programmable logic integrated circuit according to the first and second example embodiments.

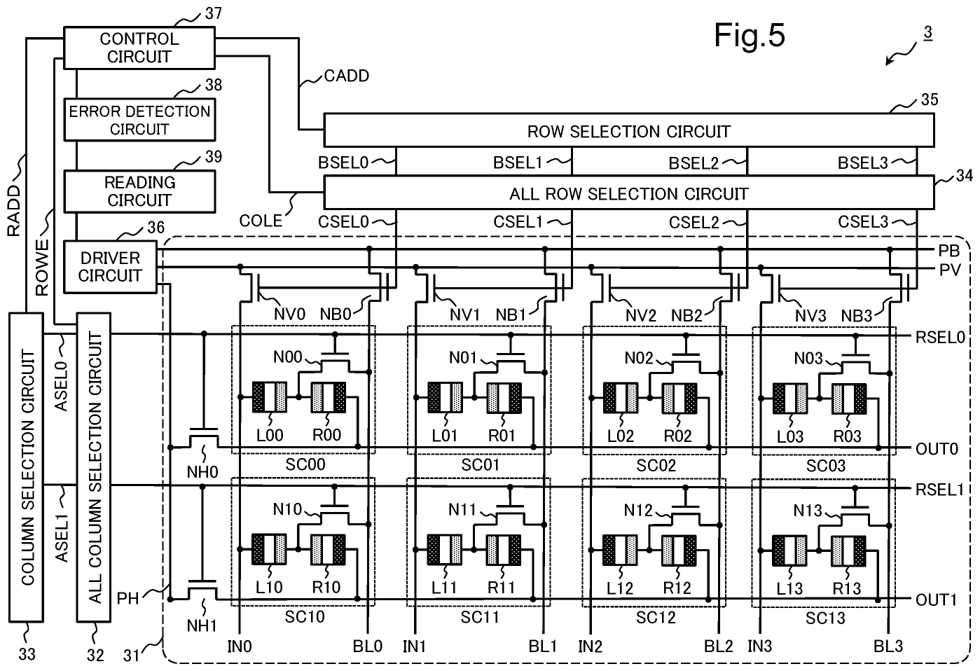

FIG. 5 is a schematic diagram illustrating one example of a circuit configuration of a programmable logic integrated circuit 3 according to the present example embodiment. The programmable logic integrated circuit 3 includes a switch array 31, an all column selection circuit 32, a column selection circuit 33, an all row selection circuit 34, a row selection circuit 35, a driver circuit 36, a control circuit 37, an error detection circuit 38, and a reading circuit 39. FIG. 5 is one example of the programmable logic integrated circuit 3, and is not intended to limit the number, arrangement, and a connection relationship of components of the programmable logic integrated circuit 3. In FIG. 5, some portions of wires connecting between the components of the programmable logic integrated circuit 3 are omitted.

The switch array 31 (within a dashed rounded rectangular frame) according to the present example embodiment is equivalent to the switch array 251 according to the second example embodiment. The all column selection circuit 32, the column selection circuit 33, the all row selection circuit 34, the row selection circuit 35, the row selection circuit 35, the driver circuit 36, the control circuit 37, the error detection circuit 38, and the reading circuit 39 according to the present example embodiment are included in the programming peripheral circuit 23 according to the second example embodiment. The control circuit 37 is connected to the all column selection circuit 32, the column selection circuit 33, the all row selection circuit 34, the row selection circuit 35, the driver circuit 36, the error detection circuit 38, and the reading circuit 39. For example, the control circuit 37 is connected to the driver circuit 36 and the reading circuit 39 via an unillustrated wire. The all column selection circuit 32 and the all row selection circuit 34 according to the present example embodiment are equivalent to the first selection circuit 12 according to the first example embodiment. The column selection circuit 33 and the row selection circuit 35 according to the present example embodiment are equivalent to the second selection circuit 13 according to the first example embodiment.

The switch array 31 has a group of N (N is an integer equal to or more than two) vertical lines extending in a column direction (also referred to as a first direction) and a group of M (M is an integer equal to or more than two) horizontal lines extending in a row direction (also referred to as a second direction).

In the example in FIG. 5, the switch array 31 has four input lines IN (also referred to as first wires) extending in the column direction and two output lines OUT (also referred to as second wires) extending in the row direction. The switch array 31 further has four bit lines BL extending in the column direction. Hereinafter, in the case of individually describing the input lines IN and the bit lines BL, a column number (0 to 3 in order from left) will be appended to the end. Similarly, in the case of individually describing the output lines OUT, a row number (0 to 1 in order from top) will be appended to the end.

The switch array 31 further has two column selection lines RSEL (also referred to as first selection lines) extending in the row direction and four row selection lines CSEL (also referred to as second selection lines) extending in the column direction. Hereinafter, in the case of individually describing the row selection lines CSEL, a column number (0 to 3 in order from left) will be appended to the end. Similarly, in the case of individually describing the column selection lines RSEL, a row number (0 to 1 in order from top) will be appended to the end.

The switch array 31 further includes a second control line PH extending in the column direction, and a first control line PV and a third control line PB extending in the row direction.

The switch array 31 is constituted of a plurality of switch cells SC (within dotted rectangular frames). Each of the plurality of switch cells SC is arranged at a part where the input line IN and the output line OUT intersect. A connection state (connected/unconnected) between the input line IN and the output line OUT is controlled by switching a resistance state (on/off) of a plurality of switch cells.

In the example in FIG. 5, the switch array 31 has eight switch cells SC at the parts where the input line IN and the output line OUT intersect. Hereinafter, in the case of individually describing the switch cells SC, a two-digit cell number will be appended to the end, like a switch cell SC00. The cell number indicates a row number (0 to 1) in the tens place and a column number (0 to 3) in the ones place.

Each of the plurality of switch cells SC included in the switch array 31 includes a first variable resistance element L, a second variable resistance element R, and a cell transistor N. The cell transistor N is a negative-channel metal oxide semiconductor (NMOS) transistor. Hereinafter, in the case of individually describing the first variable resistance element L, the second variable resistance element R, and the cell transistor N, a two-digit cell number will be appended to the end. The cell number indicates a row number (0 to 1 in order from top) in the tens place and a column number (0 to 3 in order from left) in the ones place, similarly to the switch cells SC.

One terminal of the first variable resistance element L and one terminal of the second variable resistance element R are connected to each other and form a common node. Another terminal of the first variable resistance element L is connected to the input line IN. Another terminal of the second variable resistance element R is connected to the output line OUT. A unit element (hereinafter, described as a variable resistance switch) constituted of the first variable resistance element L and the second variable resistance element R functions as a three-terminal variable resistance switch.

In the switch cell SC in FIG. 5, an inactive electrode of the first variable resistance element L and an inactive electrode of the second variable resistance element R are connected and form a common node. An active electrode of the first variable resistance element L is connected to the input line IN, and an active electrode of the second variable resistance element R is connected to the output line OUT.

The switch cell SC is defined as on when the first variable resistance element L and the second variable resistance element R are in an on state, and is defined as off when the first variable resistance element L and the second variable resistance element R are in an off state.

One end (a source or a drain) of a diffusion layer of the cell transistor N is connected to the common node of the variable resistance switch. Another end (a drain or a source) of the diffusion layer of the cell transistor N is connected to the bit line BL. A gate of the cell transistor N is connected to the column selection line RSEL. To the gate of the cell transistor N, a voltage set for the column selection line RSEL connected to the gate is applied. When a voltage equal to or more than a threshold value is applied to the gate of the cell transistor N, the common node and the bit line BL connected to the cell transistor N are brought into electrical connection.

The switch array 31 further has a plurality of NMOS transistors. Specifically, the switch array 31 has a first transistor NV, a second transistor NH, and a third transistor NB. The first transistor NV, the second transistor NH, and the third transistor NB are NMOS transistors. Hereinafter, in the case of individually describing the first transistor NV and the third transistor NB, a column number (0 to 3 in order from left) will be appended to the end. Similarly, in the case of individually describing the second transistor NH, a one-digit row number (0 to 1 in order from top) will be appended to the end.

The first transistor NV is arranged for each column of the switch array 31. One end (a source or a drain) of a diffusion layer of the first transistor NV is connected to the first control line PV. Another end (a drain or a source) of the diffusion layer of the first transistor NV is connected to the input line IN. A gate of the first transistor NV is connected to the row selection line CSEL in common with a gate of the third transistor NB. To the gate of the first transistor NV, a voltage set for the row selection line CSEL connected to the gate is applied. When a voltage equal to or more than a threshold value is applied to the gate of the first transistor NV, the input line IN and the first control line PV connected to the first transistor NV are brought into electrical connection.

The second transistor NH is arranged for each row of the switch array 31. One end (a source or a drain) of a diffusion layer of the second transistor NH is connected to the second control line PH. Another end (a drain or a source) of the diffusion layer of the second transistor NH is connected to the output line OUT. A gate of the second transistor NH is connected to the column selection line RSEL. To the gate of the second transistor NH, a voltage set for the column selection line RSEL connected to the gate is applied. When a voltage equal to or more than a threshold value is applied to the gate of the second transistor NH, the output line OUT and the second control line PH connected to the second transistor NH are brought into electrical connection.

The third transistor NB is arranged for each column of the switch array 31. One end (a source or a drain) of a diffusion layer of the third transistor NB is connected to the third control line PB. Another end (a drain or a source) of the diffusion layer of the third transistor NB is connected to the bit line BL. The gate of the third transistor NB is connected to the row selection line CSEL in common with the gate of the first transistor NV. To the gate of the third transistor NB, a voltage set for the row selection line CSEL connected to the gate is applied. When a voltage equal to or more than a threshold value is applied to the gate of the third transistor NB, the bit line BL and the third control line PB connected to the third transistor NB are brought into electrical connection.

The all column selection circuit 32 (also referred to as a first all selection circuit) is connected to the control circuit 37 via an all column selection line ROWE. The all column selection circuit 32 is also connected to the column selection line RSEL. The all column selection circuit 32 is also connected to the column selection circuit 33 via a column selection line ASEL (also referred to as a third selection line).

When the all column selection line ROWE is high level, the all column selection circuit 32 sets all of the column selection lines RSEL to high level. When the all column selection line ROWE is low level, the all column selection circuit 32 outputs an address signal of the column selection circuit 33 as is to the column selection line RSEL. Consequently, the desired column selection line RSEL is selected.

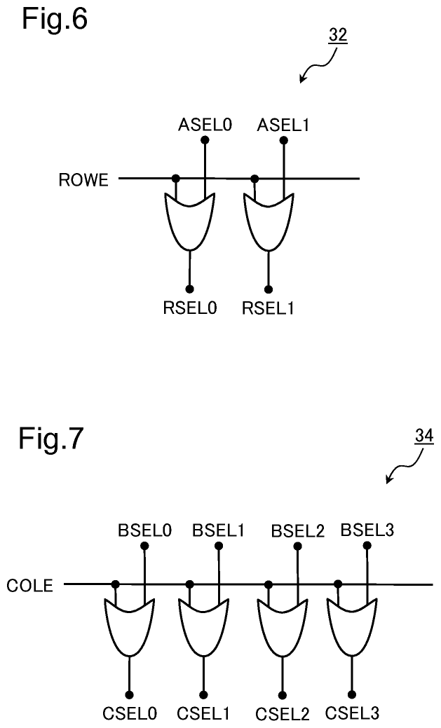

FIG. 6 is one example of the all column selection circuit 32 when the switch array 31 has a size of four columns by two rows. The all column selection circuit 32 is configured by an OR gate including the all column selection line ROWE and the column selection lines ASEL as inputs. An output of each OR gate configuring the all column selection circuit 32 is connected to the column selection line RSEL.

The column selection circuit 33 (also referred to as a first individual selection circuit) is connected to the control circuit 37 via a column address line RADD. The column selection circuit 33 is also connected to the all column selection circuit 32 via the column selection line ASEL. The column selection circuit 33 is also connected to the driver circuit 36 via the control circuit 37 or via an unillustrated wire.

The column selection circuit 33 causes the desired second transistor NH to conduct, by using any of the column selection lines RSEL. Consequently, any of the output lines OUT and the second control line PH are connected.

The column selection circuit 33 outputs, based on an address pre-decode signal, an address signal to the all column selection circuit 32. The column selection circuit 33 also outputs a decode signal for selecting the first control line PV and the third control line PB to the driver circuit 36.

The column selection circuit 33 causes the desired cell transistor N to conduct, by using any of the column selection lines RSEL. Consequently, the common node of the switch cell SC including the cell transistor N caused to conduct and the bit line BL connected to the cell transistor N are connected.

The all row selection circuit 34 (also referred to as a second all selection circuit) is connected to the control circuit 37 via an all row selection line COLE. The all row selection circuit 34 is also connected to the gates of the first transistor NV and the third transistor NB in common via the row selection line CSEL. The all row selection circuit 34 is also connected to the row selection circuit 35 via a row selection line BSEL (also referred to as a fourth selection line).

When the all row selection line COLE is high level, the all row selection circuit 34 sets all of the row selection lines CSEL to high level. When the all row selection line COLE is low level, the all row selection circuit 34 outputs an address signal of the row selection circuit 35 as is to the row selection line. Consequently, the desired row selection line CSEL is selected.

FIG. 7 is one example of the all row selection circuit 34 when the switch array 31 has a size of four columns by two rows. The all row selection circuit 34 is configured by an OR gate including the all row selection line COLE and the plurality of row selection lines BSEL as inputs. An output of each OR gate configuring the all row selection circuit 34 is connected to the row selection line CSEL on the same column as each of the row selection lines BSEL. The all row selection circuit 34 outputs an address signal of the row selection circuit 35 as is to the row selection line, and the desired row selection line is selected.

The row selection circuit 35 (also referred to as a second individual selection circuit) is connected to the control circuit 37 via a row address line CADD. The row selection circuit 35 is also connected to the all row selection circuit 34 via the plurality of row selection lines BSEL. For example, the row selection circuit 35 outputs a signal to the driver circuit 36 via the control circuit 37. The row selection circuit 35 may output a signal to the driver circuit 36 via an unillustrated wire.

The row selection circuit 35 causes the desired first transistor NV to conduct, by using any of the row selection lines CSEL. Consequently, any of the input lines IN and the first control line PV are connected.

The row selection circuit 35 causes the desired third transistor NB to conduct, by using any of the row selection lines CSEL. Consequently, any of the bit lines BL and the third control line PB are connected.

The row selection circuit 35 outputs, based on an address pre-decode signal, an address signal to the all row selection circuit 34. The row selection circuit 35 also outputs a decode signal for selecting the second control line PH to the driver circuit 36.

The driver circuit 36 is connected to the switch cell SC via the first control line PV, the second control line PH, and the third control line PB. The driver circuit 36 supplies a write voltage or a read voltage to the switch cell SC via the first control line PV, the second control line PH, and the third control line PB according to control performed by the control circuit 37.

The control circuit 37 is connected to the all column selection circuit 32 via the all column selection line ROWE. The control circuit 37 is connected to the column selection circuit 33 via the column address line RADD. The control circuit 37 is connected to the all row selection circuit 34 via the all row selection line COLE. The control circuit 37 is connected to the row selection circuit 35 via the row address line CADD. The control circuit 37 is also connected to the driver circuit 36, the error detection circuit 38, and the reading circuit 39 and controls the circuits.

The control circuit 37 receives an address A, input data D, a write enable signal WE, and a read enable signal RE as input signals, and outputs a data output Q. The control circuit 37 outputs, based on the address A, an address pre-decode signal to the row selection circuit 35 and the column selection circuit 33. When the write enable signal WE is high level, the control circuit 37 outputs, to the driver circuit 36, a driver circuit setting signal for writing input data.

When the all selection signal AL is high level, the control circuit 37 sets the all row selection line COLE and the all column selection line ROWE to high level. When the all row selection signal ALC is high level, the control circuit 37 sets the all row selection line COLE to high level and sets the all column selection line ROWE to low level. When the all selection signal AL and the all row selection signal ALC are low level, the control circuit 37 sets the all column selection line ROWE and the all row selection line COLE to low level.

When the read enable signal RE is high level, the control circuit 37 outputs, to the driver circuit 36, a driver circuit setting signal for reading data, and outputs a reading circuit control signal to the reading circuit 39. Then, the control circuit 37 receives output data IQ from the reading circuit 39, and outputs the received output data IQ to an outside as a data output Q. The control circuit 37 also outputs an error detection circuit control signal to the error detection circuit 38, and receives error information from the error detection circuit 38.

The error detection circuit 38 determines, based on the output data IQ from the reading circuit 39, whether an error is present in the switch cell SC. The error detection circuit 38 outputs a result of determination to the control circuit 37 as error information.

The reading circuit 39 is connected to the third control line PB via an unillustrated wire. The reading circuit 39 may be connected to the third control line PB via the driver circuit 36. The reading circuit 39 senses a resistance state of the switch cell SC via the third control line PB.

The above is the description about the configuration of the programmable logic integrated circuit 3 according to the present example embodiment.

Write Method

Next, a method of writing the switch cell SC will be described. Herein, a case of setting the switch cell SC00 from the off state to the on state will be described as an example. Hereinafter, the control circuit 37 will be described as a subject of an operation.

During write of the switch cell SC, the control circuit 37 sets the all row selection line COLE and the all column selection line ROWE to low level. Thus, a signal level of the row selection lines CSEL (CSEL0, CSEL1, CSEL2, and CSEL3) is consistent with a signal level of the row selection lines BSEL (BSEL0, BSEL1, BSEL2, and BSEL3). A signal level of the column selection lines RSEL (RSEL0 and RSEL1) is consistent with a signal level of the column selection lines ASEL (ASEL0 and ASEL1).

Setting

First, an example of causing the switch cell SC00 to transition from the off state to the on state will be described. In the case of causing the switch cell SC00 to transition from the off state to the on state, the first variable resistance element L00 and the second variable resistance element R00 are each set from the off state to the on state.

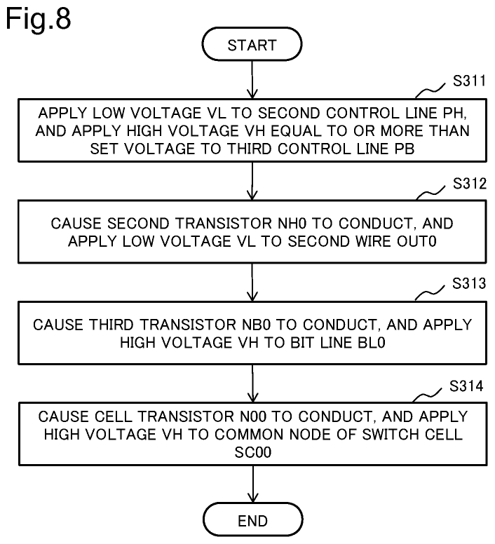

First, a procedure for setting the first variable resistance element L00 from the off state to the on state will be described along a flowchart in FIG. 8.

In FIG. 8, first, the control circuit 37 controls the driver circuit 36, and applies a low voltage VL to the second control line PH and applies a high voltage VH equal to or more than a set voltage to the third control line PB (Step S311).

Next, the control circuit 37 causes the second transistor NH0 to conduct, by using the column selection line RSEL0 being set to high level via the column selection circuit 33 and the all column selection circuit 32 (Step S312). Consequently, the low voltage VL is applied to the output line OUT0.

Next, the control circuit 37 causes the third transistor NB0 to conduct, by using the row selection line CSEL0 being set to high level via the row selection circuit 35 and the all row selection circuit 34 (Step S313). Consequently, the high voltage VH is applied to the bit line BL0.

Next, the control circuit 37 causes the cell transistor N00 to conduct, by using the column selection line RSEL0 being set to high level via the column selection circuit 33 and the all column selection circuit 32 (Step S314). Consequently, the high voltage VH is applied to a first electrode (the common node of the switch cell SC00) of the first variable resistance element L00.

With the above-described procedure, the first variable resistance element L00 transitions to the on state.

The control circuit 37 may control the driver circuit 36 and set the first control line PV to an intermediate voltage (VH+VL)/2 or high impedance. In that case, the control circuit 37 causes the first transistor NV0 to conduct, by using the row selection line CSEL0 being set to high level via the row selection circuit 35 and the all row selection circuit 34, and connects the first control line PV with the input line IN0. At this time, since a voltage equal to or less than the set voltage is applied to the second variable resistance element R00, the second variable resistance element R00 remains in the off state and undergoes no change.

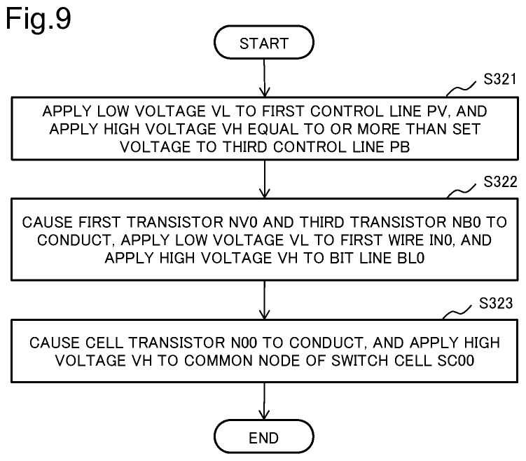

Second, a procedure for setting the second variable resistance element R00 from the off state to the on state will be described along a flowchart in FIG. 9.

In FIG. 9, first, the control circuit 37 controls the driver circuit 36, and applies a low voltage VL to the first control line PV and applies a high voltage VH equal to or more than a set voltage to the third control line PB (Step S321).

Next, the control circuit 37 causes the first transistor NV0 and the third transistor NB0 to conduct, by using the row selection line CSEL0 being set to high level via the row selection circuit 35 and the all row selection circuit 34 (Step S322). Consequently, the low voltage VL is applied to the input line IN0 and the high voltage VH is applied to the bit line BL0.

Next, the control circuit 37 causes the cell transistor N00 to conduct, by using the column selection line RSEL0 being set to high level via the column selection circuit 33 and the all column selection circuit 32 (Step S323). Consequently, the high voltage VH is applied to a first electrode (the common node of the switch cell SC00) of the second variable resistance element R00.

With the above-described procedure, the second variable resistance element R00 transitions to the on state.

The control circuit 37 may control the driver circuit 36 and set the second control line PH to an intermediate voltage (VH+VL)/2 or high impedance. In that case, the control circuit 37 causes the second transistor NH0 to conduct, by using the column selection line RSEL0 being set to high level via the column selection circuit 33 and the all column selection circuit 32, and connects the second control line PH with the output line OUT0. At this time, since a voltage equal to or less than the set voltage is applied to the first variable resistance element L00, the first variable resistance element L00 remains in the on state and undergoes no change.

With the above-described operation, the first variable resistance element L00 and the second variable resistance element R00 are set, and the switch cell SC00 comes in the on state. The order to set the first variable resistance element L00 and the second variable resistance element R00 is not limited.

Resetting

Next, an example of causing the switch cell SC00 to transition from the on state to the off state will be described. In the case of causing the switch cell SC00 to transition from the on state to the off state, the first variable resistance element L and the second variable resistance element R are each reset from the on state to the off state.

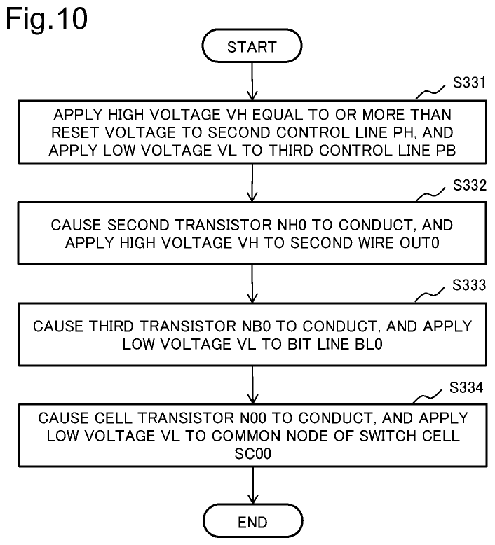

First, a procedure for resetting the first variable resistance element L00 from the on state to the off state will be described by using a flowchart in FIG. 10.

In FIG. 10, first, the control circuit 37 controls the driver circuit 36, and applies a high voltage VH equal to or more than a reset voltage to the second control line PH and applies a low voltage VL to the third control line PB (Step S331).

Next, the control circuit 37 causes the second transistor NH0 to conduct, by using the column selection line RSEL0 being set to high level via the column selection circuit 33 and the all column selection circuit 32 (Step S332). Consequently, the high voltage VH is applied to the output line OUT0.

Next, the control circuit 37 causes the third transistor NB0 to conduct, by using the row selection line CSEL0 being set to high level via the row selection circuit 35 and the all row selection circuit 34 (Step S333). Consequently, the low voltage VL is applied to the bit line BL0.

Next, the control circuit 37 causes the cell transistor N00 to conduct, by using the column selection line RSEL0 being set to high level via the column selection circuit 33 and the all column selection circuit 32 (Step S334). Consequently, the low voltage VL is applied to a first electrode (the common node of the switch cell SC00) of the first variable resistance element L00.

With the above-described procedure, the first variable resistance element L00 transitions to the off state.

The control circuit 37 may control the driver circuit 36 and set the first control line PV to an intermediate voltage (VH+VL)/2 or high impedance. In that case, the control circuit 37 causes the first transistor NV0 to conduct, by using the row selection line CSEL0 being set to high level via the row selection circuit 35 and the all row selection circuit 34, and connects the first control line PV with the input line IN0. At this time, since a voltage equal to or less than the reset voltage is applied to the second variable resistance element R00, the second variable resistance element R00 remains in the on state and undergoes no change.

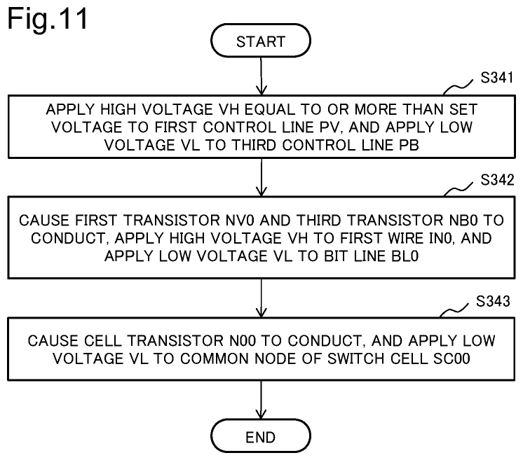

Second, a procedure for resetting the second variable resistance element R00 from the on state to the off state will be described by using a flowchart in FIG. 11.

In FIG. 11, first, the control circuit 37 controls the driver circuit 36, and applies a high voltage VH equal to or more than a reset voltage to the first control line PV and applies a low voltage VL to the third control line PB (Step S341).

Next, the control circuit 37 causes the first transistor NV0 and the third transistor NB0 to conduct, by using the row selection line CSEL0 being set to high level via the column selection circuit 33 and the all column selection circuit 32. Consequently, the high voltage VH is applied to the input line IN0, and the low voltage VL is applied to the bit line BL0 (Step S342).

Next, the control circuit 37 causes the cell transistor N00 to conduct, by using the column selection line RSEL0 being set to high level via the row selection circuit 35 and the all row selection circuit 34. Consequently, the low voltage VL is applied to a first electrode of the second variable resistance element R00 (the common node of the switch cell SC00) (Step S343).

With the above-described procedure, the second variable resistance element R00 transitions to the off state.

The control circuit 37 may control the driver circuit 36 and set the second control line PH to an intermediate voltage (VH+VL)/2 or high impedance. In that case, the control circuit 37 causes the second transistor NH0 to conduct, by using the column selection line RSEL0 being set to high level via the column selection circuit 33 and the all column selection circuit 32, and connects the second control line PH with the output line OUT0. At this time, since a voltage equal to or less than the reset voltage is applied to the first variable resistance element L00, the first variable resistance element LOO remains in the off state and undergoes no change.

With the above-described operation, the first variable resistance element L00 and the second variable resistance element R00 are reset, and the switch cell SC00 comes in the off state. The order to reset the first variable resistance element L00 and the second variable resistance element R00 is not limited.

The above is the description about the method of writing the switch cell SC.

First Read Method

Next, a first method of reading the switch cell SC will be described. Herein, a case of reading a state of the switch cell SC00 included in the switch array 31 will be described as an example. Hereinafter, the control circuit 37 will be described as a subject of an operation.

In the first method of reading the switch cell SC, the control circuit 37 sets the all row selection line COLE and the all column selection line ROWE to low level. Thus, a signal level of the row selection lines CSEL (CSEL0, CSEL1, CSEL2, and CSEL3) is consistent with a signal level of the row selection lines BSEL (BSEL0, BSEL1, BSEL2, and BSEL3). A signal level of the column selection lines RSEL (RSEL0 and RSEL1) is consistent with a signal level of the column selection lines ASEL (ASEL0 and ASEL1).

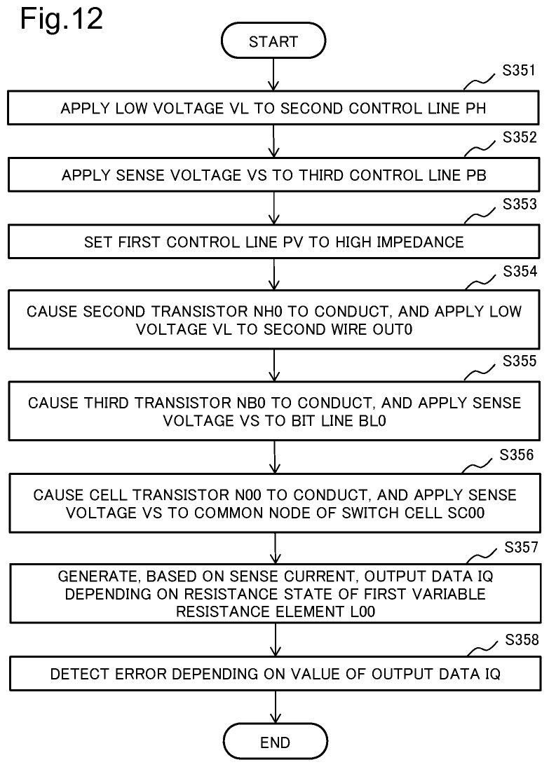

First, a procedure for reading a resistance state of the first variable resistance element L00 will be described along a flowchart in FIG. 12.

In FIG. 12, first, the control circuit 37 controls the driver circuit 36, and applies a low voltage VL to the second control line PH (Step S351).

The control circuit 37 controls the reading circuit 39, and applies a sense voltage VS to the third control line PB (Step S352).

The control circuit 37 controls the driver circuit 36, and sets the first control line PV to high impedance (Step S353).

Next, the control circuit 37 causes the second transistor NH0 to conduct, by using the column selection line RSEL0 being set to high level via the column selection circuit 33 and the all column selection circuit 32 (Step S354). Consequently, the low voltage VL is applied to the output line OUT0.

Next, the control circuit 37 causes the third transistor NB0 to conduct, by using the row selection line CSEL0 being set to high level via the row selection circuit 35 and the all row selection circuit 34 (Step S355). Consequently, the sense voltage VS is applied to the bit line BL0.

Next, the control circuit 37 causes the cell transistor N00 to conduct, by using the column selection line RSEL0 being set to high level via the column selection circuit 33 and the all column selection circuit 32 (Step S356). Consequently, the sense voltage VS is applied to a first electrode (the common node of the switch cell SC00) of the first variable resistance element L00.

With the above-described procedure, a sense current depending on the resistance state of the first variable resistance element L00 flows.

The control circuit 37 generates, by using the reading circuit 39, output data IQ depending on the resistance state of the first variable resistance element L00, based on the sense current (Step S357). For example, the reading circuit 39 converts the sense current into a voltage, then compares the voltage with a reference voltage, and determines the resistance state of the first variable resistance element L00. For example, the reading circuit 39 outputs, as the output data IQ, data 1 when a resistance value of the first variable resistance element L00 is smaller than a predetermined value, or data 0 when the resistance value of the first variable resistance element L00 is larger than the predetermined value.

The control circuit 37 detects, by using the error detection circuit 38, an error depending on a value of the output data IQ (Step S358). For example, in the case of the output data 0, the error detection circuit 38 determines that the resistance state of the first variable resistance element L00 is an expected state (off state). For example, in the case of the output data 1, the error detection circuit 38 determines that the resistance state of the first variable resistance element L00 is not an expected state (on state).

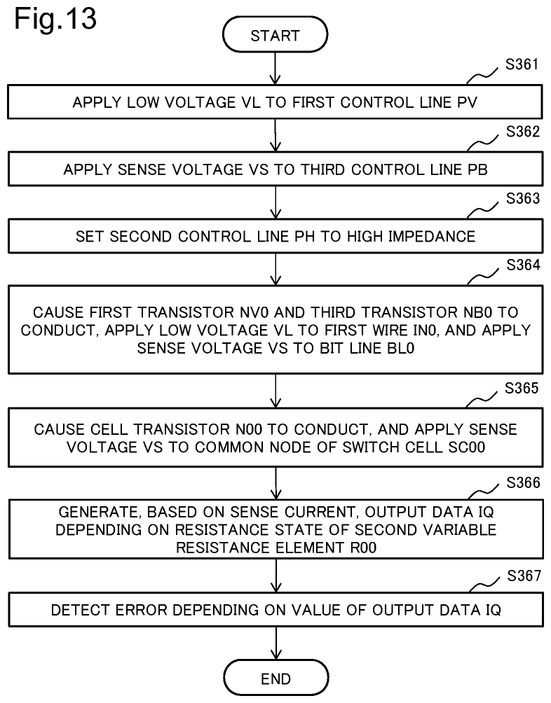

Second, a procedure for reading a resistance state of the second variable resistance element R00 will be described along a flowchart in FIG. 13.

In FIG. 13, first, the control circuit 37 controls the driver circuit 36, and applies a low voltage VL to the first control line PV (Step S361).

The control circuit 37 controls the reading circuit 39, and applies a sense voltage VS to the third control line PB (Step S362).

The control circuit 37 controls the driver circuit 36, and sets the second control line PH to high impedance (Step S363).

Next, the control circuit 37 causes the first transistor NV0 and the third transistor NB0 to conduct, by using the row selection line CSEL0 being set to high level via the row selection circuit 35 and the all row selection circuit 34 (Step S364). Consequently, the low voltage VL is applied to the input line IN0, and the sense voltage VS is applied to the bit line BL0.

Next, the control circuit 37 causes the cell transistor N00 to conduct, by using the column selection line RSEL0 being set to high level via the column selection circuit 33 and the all column selection circuit 32 (Step S365). Consequently, the sense voltage VS is applied to a first electrode (the common node) of the second variable resistance element R00.

With the above-described procedure, a sense current depending on the resistance state of the second variable resistance element R00 flows.

The control circuit 37 generates, by using the reading circuit 39, output data IQ depending on the resistance state of the second variable resistance element R00, based on the sense current (Step S366). For example, the reading circuit 39 converts the sense current into a voltage, then compares the voltage with a reference voltage, and determines the resistance state of the second variable resistance element R00. For example, the reading circuit 39 outputs, as the output data IQ, data 1 when a resistance value of the second variable resistance element R00 is smaller than a predetermined value, or data 0 when the resistance value of the second variable resistance element R00 is larger than the predetermined value.

The control circuit 37 detects, by using the error detection circuit 38, an error depending on a value of the output data IQ (Step S367). For example, in the case of the output data 0, the error detection circuit 38 determines that the resistance state of the second variable resistance element R00 is an expected state (off state). For example, in the case of the output data 1, the error detection circuit 38 determines that the resistance state of the second variable resistance element R00 is not an expected state (on state).

The above is the description about the first method of reading the switch cell SC.

Second Read Method

Next, a second method of reading the switch cell SC will be described. The second read method is applied when a resistance state expected for the variable resistance switches is the off state. When rewrite is performed on the programmable logic circuit, all of the variable resistance switches are brought into the off state and then write is performed. At this time, a resistance state expected for all of the variable resistance switches is the off state. However, in the case of insufficient write, or in the case of failure in a circuit operation, there is a possibility that a variable resistance switch being in a resistance state (on state) different from the expected resistance state (off state) may be present. Thus, a resistance state of all of the switches is confirmed as being the expected state (off state) before programming of the programmable logic circuit. Hereinafter, the control circuit 37 will be described as a subject of an operation.

First, the control circuit 37 sets the all row selection line COLE and the all column selection line ROWE to high level. Thus, all of the row selection lines CSEL (CSEL0, CSEL1, CSEL2, and CSEL3) are set to high level, regardless of a signal of the row selection circuit 35. Similarly, a signal level of all of the column selection lines RSEL (RSEL0 and RSEL1) is also set to high level.

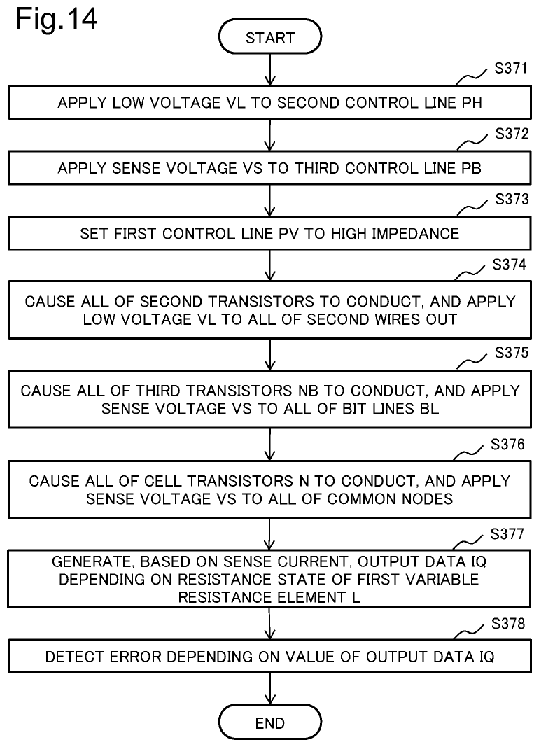

First, a procedure for reading a resistance state of the first variable resistance element L will be described along a flowchart in FIG. 14.

In FIG. 14, first, the control circuit 37 controls the driver circuit 36, and applies a low voltage VL to the second control line PH (Step S371).

The control circuit 37 controls the reading circuit 39, and applies a sense voltage VS to the third control line PB (Step S372).

The control circuit 37 controls the driver circuit 36, and sets the first control line PV to high impedance (Step S373).

Next, the control circuit 37 causes all of the second transistors NH (NH0 and NH1) to conduct, by using all of the column selection lines RSEL (RSEL0 and RSEL1) being set to high level via the all column selection circuit 32 (Step S374). Consequently, the low voltage VL is applied to all of the output lines OUT (OUT0 and OUT1).

Next, the control circuit 37 causes all of the third transistors NB (NB0, NB1, NB2, and NB3) to conduct, by using all of the row selection lines CSEL (CSEL0, CSEL1, CSEL2, and CSEL3) being set to high level via the all row selection circuit 34 (Step S375). Consequently, the sense voltage VS is applied to all of the bit lines BL (BL0, BL1, BL2, and BL3).

Next, the control circuit 37 causes all of the cell transistors N (N00, N01, N02, N03, N10, N11, N12, and N13) to conduct, by using all of the column selection lines RSEL (RSEL0 and RSEL1) being set to high level via the all column selection circuit 32. Consequently, the sense voltage VS is applied to a first electrode (the common node of all of the switch cells SC) of all of the first variable resistance elements L (L00, L01, L02, L03, L10, L11, L12, and L13) (Step S376).

With the above-described procedure, all of the first variable resistance elements L (L00, L01, L02, L03, L10, L11, L12, and L13) are connected in parallel with the first control line PV and the third control line PB. Consequently, a total sum of the sense currents flowing through all of the first variable resistance elements L included in the switch array 31 flows through the first control line PV and the third control line PB.

The control circuit 37 generates, by using the reading circuit 39, output data IQ depending on the resistance state of the first variable resistance element, based on the sense current (Step S377). For example, the reading circuit 39 converts the sense current into a voltage, then compares the voltage with a reference voltage, and determines the resistance state of the first variable resistance element L. For example, the reading circuit 39 outputs, as the output data IQ, data 1 when a resistance value is smaller than a predetermined value, or data 0 when the resistance value is larger than the predetermined value.

The control circuit 37 detects, by using the error detection circuit 38, an error depending on a value of the output data IQ (Step S378). For example, in the case of the output data 0, the error detection circuit 38 determines that the resistance state of all of the first variable resistance elements L is an expected state (off state). For example, in the case of the output data 1, the error detection circuit 38 determines that the resistance state of any of the first variable resistance elements L is not an expected state (a switch in the on state is included).

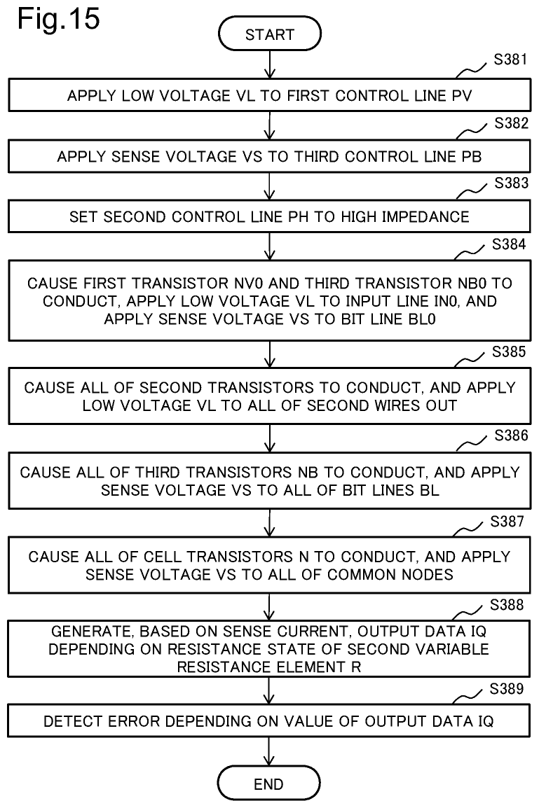

Second, a procedure for reading a resistance state of the second variable resistance element R will be described along a flowchart in FIG. 15.

First, the control circuit 37 controls the driver circuit 36, and applies a low voltage VL to the first control line PV (Step S381).

The control circuit 37 controls the reading circuit 39, and applies a sense voltage VS to the third control line PB (Step S382).

The control circuit 37 controls the driver circuit 36, and sets the second control line PH to high impedance (Step S383).

Next, the control circuit 37 causes the first transistor NV0 and the third transistor NB0 to conduct, by using the row selection line CSEL0 being set to high level via the row selection circuit 35 and the all row selection circuit 34 (Step S384). Consequently, the low voltage VL is applied to the input line IN0, and the sense voltage VS is applied to the bit line BL0.

Next, the control circuit 37 causes all of the second transistors NH (NH0 and NH1) to conduct, by using all of the column selection lines RSEL (RSEL0 and RSEL1) being set to high level via the all column selection circuit 32 (Step S385). Consequently, all of the output lines OUT (OUT0 and OUT1) are set to high impedance.

Next, the control circuit 37 causes all of the third transistors NB (NB0, NB1, NB2, and NB3) to conduct, by using all of the row selection lines CSEL (CSEL0, CSEL1, CSEL2, and CSEL3) being set to high level via the all row selection circuit 34 (Step S386). Consequently, the sense voltage VS is applied to all of the bit lines BL (BL0, BL1, BL2, and BL3).

Next, the control circuit 37 causes all of the cell transistors N (N00, N01, N02, N03, N10, N11, N12, and N13) to conduct, by using all of the column selection lines RSEL (RSEL0 and RSEL1) being set to high level via the all column selection circuit 32 (Step S387). Consequently, the sense voltage VS is applied to a first electrode (the common node of all of the switch cells SC) of all of the second variable resistance elements R (R00, R01, R02, R03, R10, R11, R12, and R13).

With the above-described procedure, all of the second variable resistance elements R (R00, R01, R02, R03, R10, R11, R12, and R13) are connected in parallel with the second control line PH and the third control line PB. Consequently, a total sum of the sense currents flowing through all of the second variable resistance elements R included in the switch array 31 flows through the second control line PH and the third control line PB.

The control circuit 37 generates, by using the reading circuit 39, output data IQ depending on the resistance state of the second variable resistance element R, based on the sense current (Step S388). For example, the reading circuit 39 converts the sense current into a voltage, then compares the voltage with a reference voltage, and determines the resistance state of the second variable resistance element R. For example, the reading circuit 39 outputs, as the output data IQ, data 1 when a resistance value is smaller than a predetermined value, or outputs data 0 when the resistance value is larger than the predetermined value.

The control circuit 37 detects, by using the error detection circuit 38, an error depending on a value of the output data IQ (Step S389). For example, in the case of the output data 0, the error detection circuit 38 determines that the resistance state of all of the second variable resistance elements R is an expected state (off state). For example, in the case of the output data 1, the error detection circuit 38 determines that the resistance state of any of the second variable resistance elements R is not an expected state (a switch in the on state is included).

The above is the description about the second method of reading the switch cell SC.

Third Read Method

Next, a third method of reading the switch cell SC will be described. The third read method can be used for quickly determining whether write in the variable resistance switch is correctly performed. In the case of the switch array with N rows and M columns, reading for the number of times as many as the number of switches, that is, reading for M×N times is necessary in the first read method, in order to determine a resistance state (on/off) of the first variable resistance element L included in the switch array 31. On the other hand, in the third read method, it is possible to determine acceptability of a resistance state by reading for the number of times as many as the number of columns, that is, M times.

However, the third read method requires the following conditions 1 to 4.

(Condition 1) The number of faults in the first variable resistance elements L in each column is one or less.
(Condition 2) The number of faults in the variable resistance switches in each column is one or less.
(Condition 3) Only one of the first variable resistance elements L in each column is in the on state.
(Condition 4) Only one of the second variable resistance elements R in each column is in the on state.
The third read method can be applied when the above-described conditions 1 to 4 are all satisfied.

In general, a switch array for use in a programmable logic circuit is programmed in such a way that only one of variable resistance switches in each column is in the on state. Thus, the above-described conditions 3 and 4 are satisfied. A write failure rate of a variable resistance switch is equal to or less than ten to the power of minus six. Thus, when N is less than one hundred, a probability that any of the conditions 1 and 2 is unsatisfied is a very low probability being equal to or less than ten to the power of minus ten.

The third read method in the case of M=4 and N=2 will be described below.

First, the control circuit 37 sets the all row selection line COLE to high level. Consequently, a signal level of all of the row selection lines CSEL (CSEL0, CSEL1, CSEL2, and CSEL3) is high level, regardless of a signal of the row selection circuit 35. The control circuit 37 sets the all column selection line ROWE to low level. Consequently, a signal level of the column selection lines RSEL (RSEL0 and RSEL1) is consistent with a signal level of the column selection lines ASEL (ASEL0 and ASEL1).

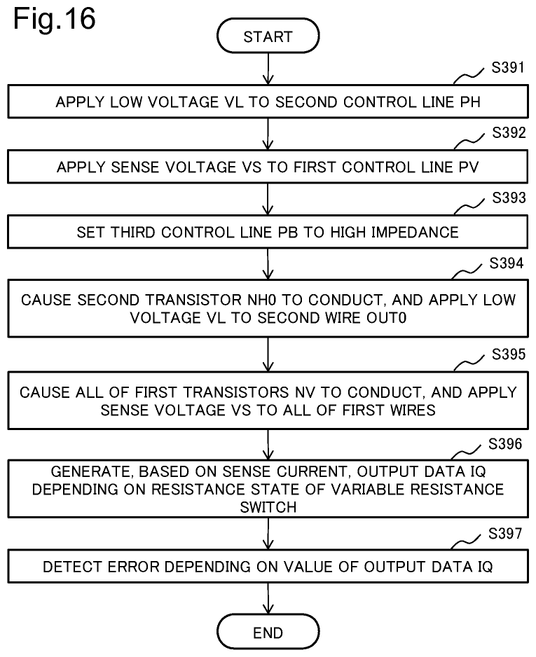

Herein, a procedure for reading a resistance state of the variable resistance switch in the switch array 31 will be described by using a flowchart in FIG. 16.

First, the control circuit 37 controls the driver circuit 36, and applies a low voltage VL to the second control line PH (Step S391).

The control circuit 37 controls the reading circuit 39, and applies a sense voltage VS to the first control line PV (Step S392).

The control circuit 37 controls the driver circuit 36, and sets the third control line PB to high impedance (Step S393).

Next, the control circuit 37 causes the second transistor NH0 to conduct, by using the column selection line RSEL0 being set to high level via the column selection circuit 33 and the all column selection circuit 32 (Step S394). Consequently, the low voltage VL is applied to the output line OUT0. At this time, the column selection line RSEL1 is low level, and the second transistor NH1 does not conduct.

Next, the control circuit 37 causes all of the first transistors NV (NV0, NV1, NV2, and NV3) to conduct, by using all of the row selection lines CSEL (CSEL0, CSEL1, CSEL2, and CSEL3) being set to high level via the all row selection circuit 34 (Step S395). Consequently, the sense voltage VS is applied to all of the input lines IN (IN0, IN1, IN2, and IN3).

With the above-described procedure, the variable resistance switches belonging to the same column are each connected with the first control line PV and the third control line PB. Consequently, a total sum of the sense currents flowing through all of the first variable resistance elements L belonging to the same column within the switch array 31 flows through the first control line PV and the second control line PH.

The control circuit 37 generates, by using the reading circuit 39, output data IQ depending on the resistance state of the second variable resistance element R, based on the sense current (Step S396). For example, the reading circuit 39 converts the sense current into a voltage, then compares the voltage with a reference voltage, and determines the resistance state of the variable resistance switch. For example, the reading circuit 39 outputs, as the output data IQ, data 1 when a resistance value is smaller than a predetermined value, or outputs data 0 when the resistance value is larger than the predetermined value.

The error detection circuit 38 detects an error depending on a value of the output data IQ (Step S397). For example, in the case of the output data 0, the error detection circuit 38 determines that the resistance state of all of the variable resistance switches is an expected state (off state). For example, in the case of the output data 1, the error detection circuit 38 determines that the resistance state of any of the variable resistance switches is not an expected state (a switch in the on state is included).

The above is the description about the third method of reading the switch cell SC.

As described above, the programmable logic integrated circuit according to the present example embodiment is able to provide a programmable logic integrated circuit capable of quickly determining an error in a variable resistance switch constituting a crossbar switch.

For example, a first selection circuit includes a first all selection circuit and a second all selection circuit. The first all selection circuit collectively selects a plurality of variable resistance switches aligned in a second direction. The second all selection circuit collectively selects a plurality of variable resistance switches aligned in a first direction. A second selection circuit includes a first individual selection circuit and a second individual selection circuit. The first individual selection circuit is connected to the first all selection circuit and individually selects a variable resistance element included in the plurality of variable resistance switches aligned in the second direction. The second individual selection circuit is connected to the second all selection circuit and individually selects a variable resistance element included in the plurality of variable resistance switches aligned in the first direction.

For example, a switch cell includes a cell transistor that has one end of a diffusion layer connected to a common node between two variable resistance elements. A switch array includes a first wire, a second wire, a bit wire, a first transistor, a second transistor, a third transistor, a first control line, a second control line, a third control line, a first selection line, a second selection line, a third selection line, and a fourth selection line. The plurality of first wires extend in the first direction, and one end of the variable resistance switch is connected thereto. The plurality of second wires extend in the second direction intersecting with the first direction, and another end of the variable resistance switch is connected thereto. The plurality of bit wires extend in the first direction, and another end of the diffusion layer of the cell transistor is connected thereto. The plurality of first transistors have one end of a diffusion layer connected to the first wire. Another end of the diffusion layer of the plurality of first transistors is connected to the first control line. The plurality of second transistors have one end of a diffusion layer connected to the second wire. Another end of the diffusion layer of the plurality of second transistors is connected to the second control line. The plurality of third transistors have one end of a diffusion layer connected to the bit wire. Another end of the diffusion layer of the plurality of third transistors is connected to the third control line. The plurality of first selection line are connected to the first all selection circuit. To each of the plurality of first selection lines, a gate of the cell transistor included in a plurality of switch cells aligned in the second direction is connected in common, and a gate of the second transistor associated with the plurality of switch cells aligned in the second direction is connected. The plurality of second selection line are connected to the second all selection circuit. To each of the plurality of second selection lines, gates of the first transistor and the second transistor associated with the plurality of switch cells aligned in the first direction are connected in common. The third selection line is connected to the first individual selection circuit, and is connected to each of the plurality of first selection lines via the first all selection circuit. The fourth selection line is connected to the second individual selection circuit, and is connected to each of the plurality of second selection lines via the second all selection circuit.

For example, the programmable logic integrated circuit according to the present example embodiment includes a control circuit that is connected to the first all selection circuit, the second all selection circuit, the first individual selection circuit, the second individual selection circuit, the reading circuit, and the error detection circuit, and sets a voltage to be applied to the first control line, the second control line, and the third control line. The programmable logic integrated circuit according to the present example embodiment further includes a driver circuit that is connected to the control circuit, the first control line, the second control line, and the third control line, and applies a voltage to the first control line, the second control line, and the third control line according to control of the control circuit. When reading a resistance state of the variable resistance element to be selected, the control circuit controls the driver circuit and sets a voltage to be applied to the first control line and the second control line. The control circuit controls the reading circuit and sets a voltage to be applied to the third control line. The control circuit controls at least any of the first all selection circuit and the first individual selection circuit and sets a voltage to be applied to a gate of any of the first transistors and the third transistors. The control circuit controls at least any of the second all selection circuit and the second individual selection circuit and sets a voltage to be applied to a gate of any of the second transistors.

While the invention has been particularly shown and described with reference to exemplary embodiments thereof, the invention is not limited to these embodiments. It will be understood by those of ordinary skill in the art that various changes in form and details may be made therein without departing from the spirit and scope of the present invention as defined by the claims.

This application is based upon and claims the benefit of priority from Japanese patent application No. 2018-046136, filed on Mar. 14, 2018, the disclosure of which is incorporated herein in its entirety by reference.

### REFERENCE SIGNS LIST

1, 2, 3 Programmable logic integrated circuit

11 Switch array

12 First selection circuit

13 Second selection circuit

14 Reading circuit

15 Error detection circuit

21 Configuration port

22 Configuration circuit

23 Programming peripheral circuit

25 Programmable logic cell

26 General-purpose port

31 Switch array

32 All column selection circuit

33 Column selection circuit

34 All row selection circuit

35 Row selection circuit

36 Driver circuit

37 Control circuit

38 Error detection circuit

39 Reading circuit

100 Variable resistance switch

110 Variable resistance element

111 Active electrode

112 Inactive electrode

113 Variable resistance layer

114 Common node

115 Metal crosslink

251 Switch array

252 Fundamental logic circuit

What is claimed is:

1. A semiconductor device comprising:
a switch array in which a switch cell including a variable resistance switch is arranged at each location where a plurality of wires constituting a crossbar switch intersect;
a first selection circuit that selects all of the variable resistance switches included in the switch array;
a second selection circuit that selects any of the variable resistance switches included in the switch array;
a reading circuit that reads a state of the variable resistance switch selected by any of the first selection circuit and the second selection circuit; and
an error detection circuit that detects, based on a state of the variable resistance switch read by the reading circuit, an error in at least any of the variable resistance switches included in the switch array.

2. The semiconductor device according to claim 1, wherein
the variable resistance switch is constituted of two variable resistance elements connected in series,
the reading circuit reads that the variable resistance switch is in an on state when at least one of the two variable resistance elements constituting the variable resistance switch is in an on state, reads that the variable resistance switch is in an off state when both of the two variable resistance elements constituting the variable resistance switch are in an off state, and outputs, to the error detection circuit, output data depending on a resistance state of the variable resistance element constituting the variable resistance switch, and
the error detection circuit determines, based on the output data from the reading circuit, whether an error is present in a resistance state of the variable resistance switch.

3. The semiconductor device according to claim 2, wherein
the first selection circuit selects one of the two variable resistance elements constituting all of the variable resistance switches included in the switch array when all of a plurality of the variable resistance switches included in the switch array are expected as being in an off state, and
the reading circuit outputs, as the output data to the error detection circuit, a result of determining at least one resistance state among all of the variable resistance elements selected by the first selection circuit.

4. The semiconductor device according to claim 3, wherein
the reading circuit determines that an error is present in at least any of the variable resistance elements included in the switch array when at least one resistance state among all of the variable resistance elements selected by the first selection circuit is an on state.

5. The semiconductor device according to claim 2, wherein
the first selection circuit includes:
a first all selection circuit that collectively selects one of the two variable resistance elements constituting a plurality of the variable resistance switches aligned in a second direction intersecting with a first direction; and
a second all selection circuit that collectively selects one of the two variable resistance elements constituting a plurality of the variable resistance switches aligned in the first direction, and
the second selection circuit includes:
a first individual selection circuit that is connected to the first all selection circuit and individually selects the variable resistance element included in a plurality of the variable resistance switches aligned in the second direction; and
a second individual selection circuit that is connected to the second all selection circuit and individually selects the variable resistance element included in a plurality of the variable resistance switches aligned in the first direction.

6. The semiconductor device according to claim 5, wherein
the switch cell includes
a cell transistor that has one end of a diffusion layer connected to a common node between the two variable resistance elements, and
the switch array includes:
a plurality of first wires that extend in the first direction and to which one end of the variable resistance switch is connected;
a plurality of second wires that extend in the second direction and to which another end of the variable resistance switch is connected;
a plurality of bit wires that extend in the first direction and to which another end of the diffusion layer of the cell transistor is connected;
a plurality of first transistors that have one end of a diffusion layer connected to the first wire;
a first control line to which another end of the diffusion layer of a plurality of the first transistors is connected;
a plurality of second transistors that have one end of a diffusion layer connected to the second wire;
a second control line to which another end of the diffusion layer of a plurality of the second transistors is connected;
a plurality of third transistors that have one end of a diffusion layer connected to the bit wire;
a third control line to which another end of the diffusion layer of a plurality of the third transistors is connected;
a plurality of first selection lines that are connected to the first all selection circuit, to which a gate of the cell transistor included in a plurality of the switch cells aligned in the second direction is connected in common, and to which a gate of the second transistor associated with a plurality of the switch cells aligned in the second direction is connected;
a plurality of second selection lines that are connected to the second all selection circuit and to which gates of the first transistor and the second transistor being associated with a plurality of the switch cells aligned in the first direction are connected in common;
a third selection line that is connected to the first individual selection circuit and is connected to each of a plurality of the first selection lines via the first all selection circuit; and
a fourth selection line that is connected to the second individual selection circuit and is connected to each of a plurality of the second selection lines via the second all selection circuit.

7. The semiconductor device according to claim 6, further comprising:
a control circuit that is connected to the first all selection circuit, the second all selection circuit, the first individual selection circuit, the second individual selection circuit, the reading circuit, and the error detection circuit, and sets a voltage to be applied to the first control line, the second control line, and the third control line; and
a driver circuit that is connected to the control circuit, the first control line, the second control line, and the third control line, and applies a voltage to the first control line, the second control line, and the third control line according to control of the control circuit, wherein,
when reading a resistance state of the variable resistance element to be selected,
the control circuit controls the driver circuit and sets a voltage to be applied to the first control line and the second control line, controls the reading circuit and sets a voltage to be applied to the third control line, controls at least any of the first all selection circuit and the first individual selection circuit and sets a voltage to be applied to a gate of any of the first transistors and the third transistors, and controls at least any of the second all selection circuit and the second individual selection circuit and sets a voltage to be applied to a gate of any of the second transistors.

8. The semiconductor device according to claim 1, further comprising:
a plurality of programmable logic cells that include the switch cell and a fundamental logic circuit constituted of a lookup table and a flip-flop;
a configuration circuit that acquires configuration information of a logic circuit to be configured in the programmable logic cell and transmits a signal for configuring the logic circuit in the programmable logic cell, based on the acquired configuration information; and
a general-purpose port that inputs data to be processed by the logic circuit configured in the programmable logic cell and outputs a result of an operation performed by the logic circuit.

9. An error detection method comprising:
in a switch array in which a switch cell including a variable resistance switch is arranged at each location where a plurality of wires constituting a crossbar switch intersect,
selecting all of the variable resistance switches or any of the variable resistance switches being included in the switch array;
reading a state of the selected variable resistance switch; and
detecting, based on the read state of the variable resistance switch, an error in at least any of the variable resistance switches included in the switch array.

10. The error detection method according to claim 9, further comprising:
in the switch cell in which the variable resistance switch is constituted of two variable resistance elements connected in series,
reading that the variable resistance switch is in an on state when at least one of the two variable resistance elements constituting the variable resistance switch is in an on state;
reading that the variable resistance switch is in an off state when both of the two variable resistance elements constituting the variable resistance switch are in an off state;
generating output data depending on a read resistance state of the variable resistance switch; and
determining, based on the generated output data, whether an error is present in a resistance state of the variable resistance switch.
